(19) United States
(12) Patent Application Publication
(10) Pub. No.: US 2026/0006801 A1
(43) Pub. Date: Jan. 1, 2026

(54) VERTICALLY STACKED MEMORY ARRAYS CORRESPONDING TO RESPECTIVE SINGLE DOPANT TYPES

(71) Applicant: Intel Corporation, Santa Clara, CA (US)

(72) Inventors: Abhishek Anil Sharma, Portland, OR (US); Sagar Suthram, Portland, OR (US); Wilfred Gomes, Portland, OR (US); Pushkar Ranade, San Jose, CA (US); Tahir Ghani, Portland, OR (US); Anand Murthy, Portland, OR (US)

(73) Assignee: Intel Corporation, Santa Clara, CA (US)

(21) Appl. No.: 18/759,164

(22) Filed: Jun. 28, 2024

(51) Int. Cl. H10B 80/00; H01L 23/00; H01L 25/00; H01L 25/065; H01L 25/18; H10B 10/00; H10B 12/00

(52) U.S. Cl. CPC H10B 80/00; H01L 24/08; H01L 24/80; H01L 25/0657; H01L 25/18; H01L 25/50; H10B 10/12; H10B 12/315; H01L 2224/08145; H01L 2224/80895; H01L 2224/80896; H01L 2924/1436; H01L 2924/1437

(57) ABSTRACT

Techniques and mechanisms for an integrated circuit (IC) die structure to comprise heterogeneous active layers which are stacked with each other to form structures of respective memory arrays. In an embodiment, an IC die structure comprises first metal oxide semiconductor field effect transistors (MOSFETs) of a first active layer, and second MOSFETs of a second active layer which is vertically stacked with the first active layer. A first memory array comprises the first MOSFETs, and a second memory array comprises the second MOSFETs. The first memory array comprises a four transistor (4T) static random access memory (SRAM) cell, each transistor of which corresponds to a first dopant type. The second memory array comprises a second memory cell, each transistor of which corresponds to a second dopant type. In another embodiment, a cell density of the first memory array is substantially less than that of the second memory array.

### BACKGROUND

### 1. Technical Field

This disclosure generally relates to integrated circuitry and more particularly, but not exclusively, to a vertically stacked arrangement of memory arrays.

### 2. Background Art

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and because they enable a less complicated tri-gate fabrication process. In another aspect, maintaining mobility improvement and short channel control as microelectronic device dimensions scale below the 10 nanometer (nm) node provides a challenge in device fabrication. Nanowires used to fabricate devices provide improved short channel control.

As successive generations of integrated circuit technologies continue to scale in size, speed, and power efficiency, there is expected to be an increasing premium placed on improvements to semiconductor structures and fabrication techniques.

### BRIEF DESCRIPTION OF THE DRAWINGS

The various embodiments of the present invention are illustrated by way of example, and not by way of limitation, in the figures of the accompanying drawings and in which:

FIG. 1 shows a block diagram illustrating features of a device comprising a stacked arrangement of heterogeneous memory arrays according to an embodiment.

FIG. 2 shows a flow diagram illustrating features of a method to fabricate an integrated circuit die structure comprising a vertical arrangement of heterogeneous memory arrays according to an embodiment.

FIG. 3 shows a cross-sectional side view diagram illustrating features of an integrated circuit system comprising stacked memory arrays which each correspond to a respective dopant type according to an embodiment.

FIGS. 4A through 4D show cross-sectional side view diagrams each illustrating a respective stage of processing to provide an integrated circuit device according to an embodiment.

FIGS. 5A through 5C show circuit diagrams each illustrating a respective static random access memory cell according to a corresponding embodiment.

FIGS. 6A and 6B show cross-sectional top view diagrams each illustrating a respective static random access memory cell according to an embodiment.

FIG. 7 illustrates a diagram of an example data server machine employing an integrated circuit die comprising a stacked arrangement of active layers according to an embodiment.

FIG. 8 is a block diagram of an example computing device according to an embodiment.

### DETAILED DESCRIPTION

Embodiments discussed herein variously provide techniques and mechanisms for an integrated circuit (IC) die structure to comprise heterogeneous active layers which are stacked with each other to form structures of respective memory arrays. By way of illustration and not limitation, an IC die structure comprises first metal oxide semiconductor field effect transistors (MOSFETs) of a first active layer, and second MOSFETs of a second active layer which is vertically stacked with the first active layer—e.g., wherein a first memory array comprises the first MOSFETs, and wherein a second memory array comprises the second MOSFETs.

In some embodiments, the first memory array comprises a first memory cell, wherein each MOSFET of the first memory cell corresponds to a first dopant type. Furthermore, the second memory array comprises a second memory cell, wherein each MOSFET of the second memory cell corresponds to a second dopant type. In one such embodiment, the first memory cell is of a four transistor (4T) memory cell type, and/or is of a static random access memory (SRAM) cell type. Furthermore, the second memory cell is of a cell type other than any 4T memory cell type, and/or is of a cell type other than any SRAM cell type—e.g., wherein the second memory cell is any of various dynamic random access memory (DRAM) cell types.

As used herein in the context of a dopant, or a device (such as a transistor) which comprises said dopant, the terms “dopant type,” “type of dopant,” and the like variously refer to the characteristic of the dopant being of a particular one of a positive (P) type or a negative (N) type. Some typical P-type dopants include boron, aluminum, gallium, and indium (for example), whereas some examples of N-type dopants include phosphorus, arsenic, and antimony.

Unless otherwise indicated, a device is understood herein to “correspond to a P dopant type” (for example) where any dopant of that device is some P-type dopant. For example, such a device is doped with only one dopant which is of the P-type or—alternatively—is doped with various dopants which are each of the P-type (and omits any dopant which is of a N-type). Similarly, a device is understood herein to correspond to a N dopant type where any dopant of that device is some N-type dopant (e.g., where the device omits any dopant which is of a P-type).

In the context of a given device, the terms “single dopant,” and “single metal oxide semiconductor” (or “single MOS”) are also used herein to variously refer to the characteristic of the device corresponding to one—and only one—dopant type. For example, the term “single MOS transistor” is to be understood as referring herein to a transistor which corresponds to only one of a P-dopant type or a N-dopant type. In a similar way, the term “single MOS memory cell” is to be understood as indicating that each transistor of said memory cell corresponds to the same dopant type. Furthermore, the term “single MOS memory array” is to be understood as indicating that each memory cell of said memory array corresponds to the same dopant type. Further still, the term “single MOS active layer” is to be understood as indicating that each transistor of the active layer corresponds to the same dopant type.

In enabling a stacked arrangement of memory arrays which comprise respective single MOS memory cells, where one such memory cell is of a 4T SRAM cell type, some embodiments variously facilitate efficient fabrication of tightly integrated memory resources.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including an IC die which includes a stacked arrangement of memory arrays.

The description herein includes numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Here, multiple non-silicon semiconductor material layers may be stacked within a single fin structure, for example. The multiple non-silicon semiconductor material layers may include one or more “P-type” layers that are suitable (e.g., offer higher hole mobility than silicon) for P-type transistors. The multiple non-silicon semiconductor material layers may further include one or more one or more “N-type” layers that are suitable (e.g., offer higher electron mobility than silicon) for N-type transistors. The multiple non-silicon semiconductor material layers may further include one or more intervening layers separating the N-type from the P-type layers. The intervening layers may be at least partially sacrificial, for example to allow one or more of a gate, source, or drain to wrap completely around a channel region of one or more of the N-type and P-type transistors. The multiple non-silicon semiconductor material layers may be fabricated, at least in part, with self-aligned techniques such that a stacked CMOS device may include both a high-mobility N-type and P-type transistor with a footprint of a single transistor.

For purposes of the embodiments, the transistors in various circuits, modules, and logic blocks are Tunneling FETs (TFETs). Some transistors of various embodiments may comprise metal oxide semiconductor (MOS) transistors, which include drain, source, gate, and bulk terminals. The transistors may also include Tri-Gate and FinFET transistors, Gate All Around Cylindrical Transistors, Square Wire, or Rectangular Ribbon Transistors or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors-BJT PNP/NPN, BICMOS, CMOS, etc., may be used for some transistors without departing from the scope of the disclosure.

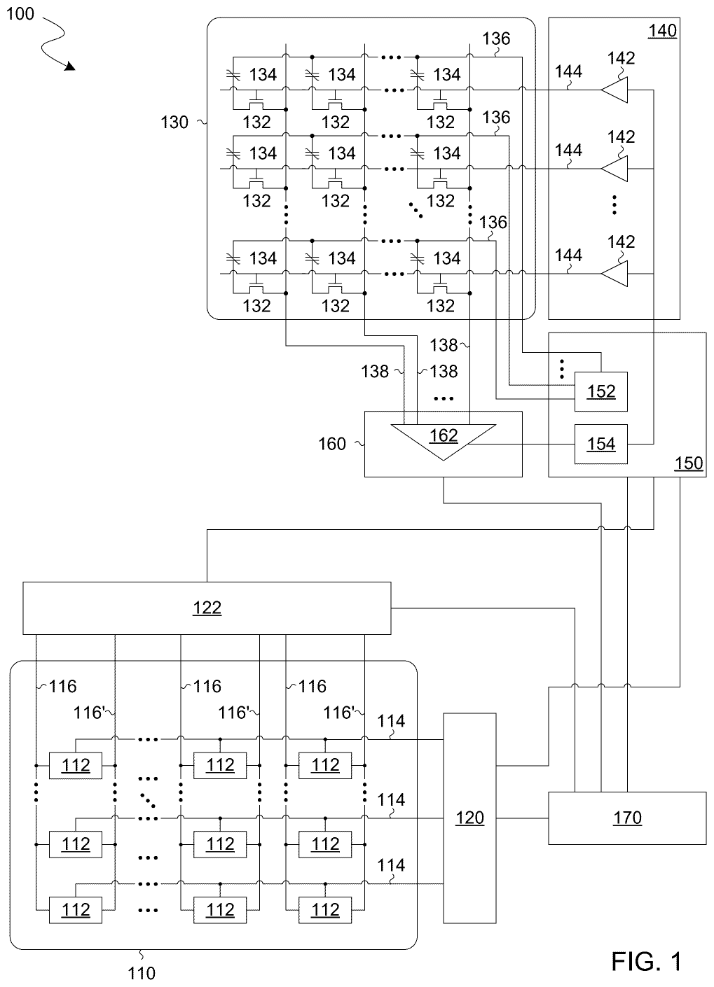

FIG. 1 shows a device 100 comprising a stacked arrangement of heterogeneous memory arrays according to an embodiment. Device 100 illustrates features of one example embodiment wherein an IC die structure comprises a vertically stacked arrangement of a plurality of layers which each comprise respective non-linear circuit components (or “active circuit components” herein) such as transistors, diodes and/or the like. One such layer (referred to herein as an “active layer,” or as a “device layer”) comprises first metal oxide semiconductor field effect transistors (MOSFETs) which are part of a first memory array, wherein another such active layer comprises second MOSFETs which are part of a second memory array. The first memory array comprises first SRAM cells which are each of a four transistor (4T) memory cell type, whereas the second memory array comprises second memory cells which are each of a different cell type—e.g., including any of various DRAM cell types.

As shown in FIG. 1, device 100 comprises a first memory array 110, a row decoder circuitry 120, and circuitry (referred to as “peripheral circuitry” or “peripheral circuit logic” herein) which is variously coupled to facilitate an accessing of memory array 110 and/or memory array 130. For example, such peripheral circuitry includes one or more sense amplifiers, driver circuits and/or any of various other circuit components which are suitable for writing of data to, refreshing data at, and/or reading data from, one or more memory arrays.

In various embodiments, an IC die structure (e.g., comprising a monolithic IC die or a composite IC die) comprises first memory cells of memory array 110 (such as the illustrative memory cells 112 shown), and second memory cells of memory array 130. Although some embodiments are not limited in this regard, one such IC die structure further comprises some or all peripheral circuitry for accessing memory array 110 and memory array 130.

In the example embodiment shown, memory array 110 includes a 2D array of memory cells 112 which are networked with conductive traces including word lines 114, multiple pairs of complementary bit lines 116, 116′. For example, each word line 114 facilitates addressing of a different respective row of memory array 110, wherein, each given pair of bit lines 116, 116′ facilitates access to a different respective column of memory array 110. As detailed herein, a given one of memory cells 112 is of a 4T SRAM cell type—i.e., where a total number of MOSFETs of the given memory cell 112 is equal to four (4). Furthermore, that given one of memory cells 112 is of a single MOS type—i.e., wherein the four MOSFET of that memory cell 112 are each a PMOS transistor, or are each an NMOS transistor.

In various embodiments, memory cells of memory array 130 are each of a cell type other than that of some or all of the memory cells 112—e.g., wherein some or all such memory cells of memory array 130 are each of a single MOS type. For example, memory cells 112 each correspond to a first dopant type, wherein the second cells of memory array 130 each correspond to a second dopant type which is the same as (or alternatively, is opposite of or otherwise different from) the first dopant type. To illustrate certain features of various embodiments, memory array 130 is described herein as including memory cells which are each of a single MOS, one transistor, one ferroelectric capacitor (1T-1F) type. However, it is to be appreciated that such description can be extended to alternative embodiments wherein such memory cells are each of any of various other suitable single MOS memory cell types (other than a 4T SRAM type).

In one such embodiment, memory array 130 includes a 2D array of storage capacitors 134 networked with conductive traces including multiple bit lines 138, word lines 144, and second capacitor plate lines 136. Memory array 130 includes a select/access transistor 132 electrically coupled to each storage capacitor 134. Each cell of memory array 130 includes or otherwise corresponds to a different respective storage capacitor 134, and to a different respective select transistor 132.

In an embodiment, the second MOSFETS of the memory array 130 are fabricated in or between back end-of-line BEOL interconnect levels of an IC die structure of device 100—e.g., wherein the first MOSFETs of memory array 110 are fabricated on a front end-of-line (or, for example, in or between other BEOL interconnect levels) of the IC die structure. For example, memory array 130 all of capacitors 134, bit lines 138, word lines 144, select transistors 132 and plate lines 136 are fabricated within, and/or between, various interconnect metallization levels, in various embodiments. In accordance with some embodiments, device 100 further comprises an additional memory array (not shown) which is also monolithically fabricated in the BEOL interconnect levels of the IC die structure, for example with substantially the same fabrication processes and process sequences employed to form memory array 130. Noting that with additional IC levels, fabrication processes (e.g., planarization) becomes more difficult, in accordance with some alternative embodiments, a memory array 130 is directly bonded to a host IC comprising a memory array 110. With the direct bonding, device 100 is referred to herein as a “composite” IC to be distinguished from both a monolithic IC and a multi-chip stack joined through first level interconnects (typically comprising solder) characteristic of IC package technology.

As further illustrated in FIG. 1, peripheral circuitry to access memory array 130 comprises at least one of column decoder circuitry 160 and row decoder circuitry 140 which (for example) is located within a transistor device level that falls within at least some of the footprint of memory array 130. For example, bit lines 138 may be electrically coupled to a sense amplifier 162 implemented with CMOS circuitry fabricated in a region of a monocrystalline semiconductor device layer (e.g., silicon substrate) that is at least partially underlying the memory array 130. In further embodiments, word lines 144 are electrically coupled to word line drivers 142, which may also be implemented with CMOS circuitry fabricated in a region of a monocrystalline semiconductor device layer (e.g., silicon substrate) that is at least partially underlying memory array 130.

In some embodiments, peripheral circuitry further includes (or is coupled to be operated with) control circuitry 150. One or more of column circuitry 160, and/or row circuitry 140, and/or memory array 130 may be electrically coupled to control circuitry 150. Control circuitry 150 may include, for example, various voltage biasing circuits, such as capacitor bias circuitry 152 that includes a charge pump that can be independently coupled to individual ones of a plurality of top capacitor plate lines 136. Hence, in addition to being able to charge up one capacitor plate through application of a voltage to bit lines, plate lines 136 may also charge up the second capacitor plates coupled to a given one of capacitor plate lines 136. Hence, rather than one plate of the storage capacitors being tied together across many word lines and many bit lines, for example by a continuous sheet of capacitor conductor, the second capacitor conductors are separated into subset populations with each subset of capacitors being associated with either one bit line or with one word line. In the example illustrated in FIG. 1, plate lines 136 run parallel to word lines 144 so that a plate of each capacitor 134 coupled to one word line 144 is tied to one plate line 136. In alternative embodiments, plate lines 136 may instead run parallel to bit lines 138 so that a plate of each capacitor 134 coupled to one bit line 138 is tied to one plate line 136. Regardless of the plate line configuration, the subset of capacitors that are electrically coupled by one capacitor plate line 136 may be coupled to a charge pump independent of the other plate lines.

Control circuitry 150 may also include, for example, various memory management circuitry, such as control logic 154 communicatively coupled into column circuitry 160 and row circuitry 140 so as to permit coordinated operation of sense amplifier 162 and word line driver 142. Control circuitry 150 may also be fabricated in a device level the falls within the footprint of memory array 130. Control circuitry 150 may, for example, also employ MOSFETs fabricated in a region of a monocrystalline semiconductor device layer (e.g., silicon substrate) that is at least partially underlying one or more of memory array 130.

Device 100 further includes host logic circuitry 170. Host logic circuitry 170 is a primary consumer of memory bandwidth supplied by memory array 130. Host logic circuitry 170 may be any application specific IC (ASIC) including one or more IP cores. In some embodiments, host logic circuitry 170 comprises a processor core. In other embodiments, host logic circuitry 170 comprises any of a wireless radio circuit, or floating point gate array (FPGA).

In the example embodiment shown, the peripheral circuitry further comprises row decoder circuitry 120 which, for accessing memory array 110, provides functionality (for example) corresponding to that of row decoder circuitry 140 for accessing memory array 130. Furthermore, the peripheral circuitry comprises column circuitry 122 which, for accessing memory array 110, provides functionality (for example) corresponding to that of column circuitry 160 for accessing memory array 130. In an embodiment, one or more of row decoder circuitry 120, and/or column circuitry 122, and/or memory array 110 may be electrically coupled to control circuitry 150 (or other suitable controller logic of device 100). Although peripheral circuitry for accessing memory array 110 is shown as being distinct from other peripheral circuitry for accessing memory array 130, in various embodiments, memory array 110 and memory array 130 share at least some common peripheral circuitry.

In some embodiments, all of the peripheral circuitry for memory arrays 110, 130 is implemented in a region of a single monocrystalline semiconductor device layer (e.g., silicon substrate). For some further embodiments where one or each of memory arrays 110, 130 is bonded to a host IC structure including the peripheral circuitry, some of the peripheral circuitry of the host IC is coupled to the one or more memory arrays through bonded interconnect features. In alternative embodiments, a second IC structure that includes memory array 130 further includes another single monocrystalline semiconductor device layer implementing peripheral circuitry for that memory array 130. Hence, for these embodiments, a host IC structure that includes peripheral circuitry may be directly bonded to a second IC structure that further includes additional peripheral circuitry which is similarly interconnected to memory array 130.

In some example embodiments, memory array 130 comprises a 2D array of metal-ferroelectric-metal (MFM) capacitors 134 fabricated in a vertical stack with a corresponding array of the access transistors 132. In some exemplary embodiments, the individual memory cells/bit-cells of memory array 130 include one access transistor 132 and one ferroelectric capacitor 134 (1T-1F). In other exemplary embodiments, the individual memory cells/bit-cells include one access transistor 132 and many (e.g., x) ferroelectric capacitors 134 (1T-xF). The 1T-xF architectures rely on the presence of many dipolar domains within a ferroelectric film, and so a 1T-1F structure may be modified to enable the writing and sensing of separate domains within the ferroelectric film.

In various embodiments, FE-capacitors 134 occupy a footprint over a substrate including logic circuitry including field effect transistors (FETs), for example implementing the peripheral circuitry as described above. In one such embodiment, CMOS FET circuitry implementing host logic circuitry 170 is adjacent to a footprint of memory array 110 and/or of memory array 130. Access transistors 132 providing word line and bit line access to the FE-capacitors reside, for example, within the BEOL substantially within the footprint of the FE-capacitor array.

In some embodiments, the access transistor 132 of a 1T-1F storage cell is a recessed channel array transistor (RCAT). RCATs are a class of field-effect transistors (FETs) in which the gate is recessed into the channel material. Recession into the channel increases the effective channel length of the transistor without increasing the transistor footprint, allowing access transistor 132 to have an area matched to that of an overlying ferroelectric capacitor 134.

In some embodiments, a first cell density of memory array 110—i.e., a density of the memory cells 112 in a horizontal plane through the IC die structure (in cells per square micron, for example)—is substantially less than a second cell density of memory array 130. In the particular context of cell density, “substantially less” refers to a density difference of at least 5%—e.g., wherein a difference between the first density and the second density is at least 5% (and in some embodiments, at least 10%) of the first density. In one such embodiment, a first linear pitch of adjoining ones of memory cells 112—e.g., along a row of memory array 110, or along a column of memory array 110—is at least 5% less than (for example, at least 10% less than) a corresponding second linear pitch of adjoining cells of ‘memory array 130. In availing of a small footprint 4T SRAM cell design (e.g., as compared to various 6T SRAM designs), in combination with single MOS transistor characteristics, some embodiments variously enable relatively low cost and efficient fabrication of tightly integrated, heterogeneous memory arrays of an IC die structure.

In some embodiments, a first responsiveness of the first MOSFETs of memory array 110 is substantially greater than a second responsiveness of the second MOSFETs of memory array 130. In one such embodiment, a transistor responsiveness is given by a possible switching speed (an average switching speed, for example), or a particular one of various ranges of possible switching speeds. For example, a metric of a given switching speed includes or is otherwise based on a period of time needed for a transistor to transition between an active (“ON”) state and an inactive (“OFF”) state. In an embodiment, such a metric represents a number of state transitions which can be performed by a transistor in a particular period of time. In the particular context of transistor responsiveness, “substantially greater” refers to a responsiveness difference of at least 5%—e.g., wherein a difference between the first responsiveness and the second responsiveness is at least 5% (and in some embodiments, at least 10%) of the first responsiveness.

By way of illustration and not limitation, transistors of one transistor type exhibit respective switching speeds which are each in a particular range of possible switching speeds—e.g., wherein transistors of another transistor type exhibit switching speeds of which are each is in a different range of switching speeds. In one such embodiment, two such ranges include respective switching speeds which correspond to each other—e.g., respective minimum switching speeds of the ranges, or respective maximum switching speeds of the ranges, or respective average switching speeds of the ranges—and which differ by at least 5%. For example, a first average switching speed, of a first range of possible switching speeds, is at least 105% (or alternatively, is not more than 95%) of a second average switching speed of a second range of possible switching speeds.

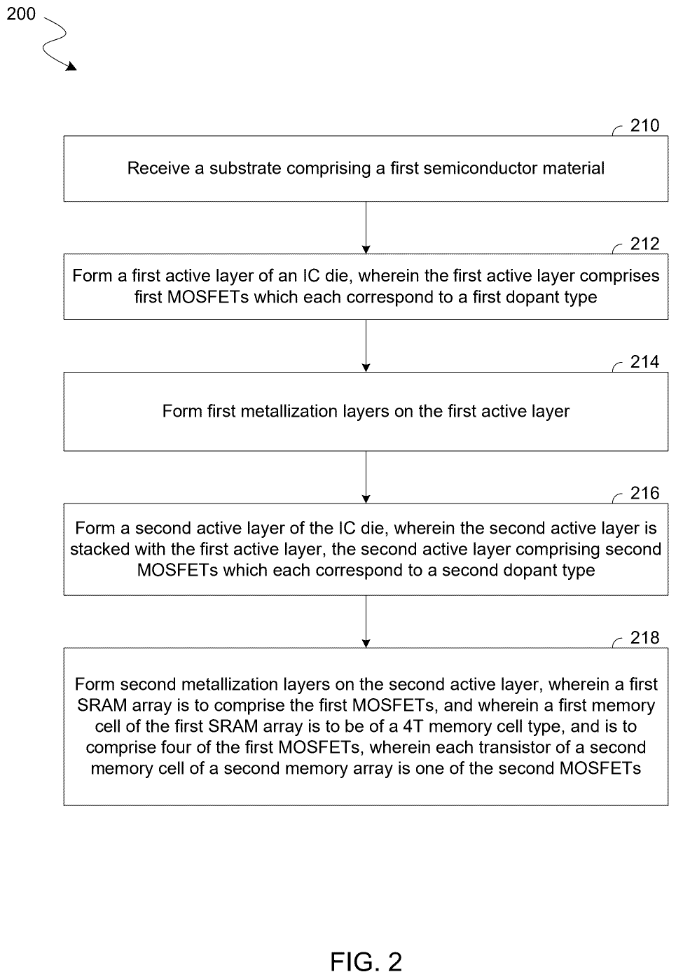

FIG. 2 shows features of a method 200 to fabricate an integrated circuit die structure comprising a vertical arrangement of heterogeneous memory arrays according to an embodiment. Method 200 illustrates one example of an embodiment which fabricates structures of an IC die to provide multiple memory arrays which each comprise respective single MOS memory cells, wherein a first memory array comprises 4T SRAM memory cells, and a second memory array comprises memory cells of a different (e.g., DRAM) type. Operations such as those of method 200 are performed, for example, to provide some or all structures of device 100.

As shown in FIG. 2, method 200 comprises (at 210) receiving a substrate comprising a first semiconductor material. By way of illustration and not limitation, the first semiconductor material comprises a monocrystalline semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In various embodiments, the first semiconductor material is a Group III-N material comprising a Group III majority constituent and nitrogen as a majority constituent (e.g., GaN, InGaN). In another embodiment, the first semiconductor material is a Group III-V material comprising a Group III majority constituent and a Group IV majority constituent (e.g., InGaAs, GaAs, GaSb, InGaSb).

Method 200 further comprises (at 212) forming, in or on the first semiconductor material, first MOSFETs of a first active layer of the IC die. In an embodiment, the first MOSFETs each correspond to a first dopant type (e.g., each to one of an n-type or a p-type). In some embodiments, method 200 is to fabricate a SRAM memory array, a first memory cell of which is to comprise multiple ones of the first MOSFETs. In one such embodiment, each transistor of the first memory cell corresponds to the first dopant type—e.g., wherein each transistor of the SRAM memory array corresponds to the first dopant type (and, in some embodiments, where each transistor of the first active layer corresponds to the first dopant type).

Method 200 further comprises (at 214) forming first metallization layers on the active layer. For example, such one or more operations comprise forming one or more initial levels of patterned interconnect metallization structures which are variously embedded in, or otherwise insulated at least partially with, dielectric material structures. In an embodiment, such one or more operations are adapted from conventional metallization techniques—e.g., wherein the patterned interconnect metallization structures at least partially enable the first memory array to be formed and/or to be subsequently coupled to peripheral circuit logic, and/or to one or more other memory arrays.

Method 200 further comprises (at 216) forming a second active layer which is stacked with the first active layer. The second active layer comprises second MOSFETs which each correspond to a second dopant type (e.g., which is the same as the first dopant type or, alternatively, is a different dopant type).

In an embodiment, the forming at 216 comprises performing any of various suitable processes which deposit a second semiconductor material on the first metallization layers—e.g., wherein said depositing is adapted from semiconductor layer transfer techniques. For example, the second semiconductor material is the same as the first semiconductor material, although some embodiments are not limited in this regard. After such depositing, one or more patterned mask, etch, deposition, and/or other suitable semiconductor fabrication operations are performed to form the second MOSFETs on the deposited substrate.

In another such embodiment, the forming at 216 comprises fabricating the second MOSFETs in or on the second semiconductor material prior to a coupling of the second active layer to the first active layer (e.g., via the first metallization layers). For example, a hybrid bond (or other) assembly process is performed to couple a combination of both the second MOSFETs and the second semiconductor material to the first active layer (e.g., via the first metallization layer). As a result, hybrid bond structures are disposed between the first metallization layers and a substrate of the second semiconductor material.

Method 200 further comprises (at 218) forming second metallization layers on the second MOSFETs. For example, the second metallization layers—e.g., in combination with the first metallization layers—at least partially enable the formation of a second memory array, and/or at least partially enable peripheral circuit logic to be coupled to one or more memory arrays.

At some point during or after method 200, a first SRAM array of the IC die comprises the first MOSFETs—e.g., wherein one or more memory cells of the first SRAM array are of a 4T memory cell type. In one such embodiment, a first such memory cell of the first SRAM array comprises four of the first MOSFETs. By contrast, a second memory array of the IC die comprises the second MOSFETs—e.g., wherein one or more memory cells of the second memory array are of memory cell type other than a 4T type and/or other than a SRAM type.

In various embodiments, method 200 further comprises other operations (not shown) by which the IC die is to include one or more other memory arrays which are vertically stacked with the first SRAM array and the second memory array. By way of illustration and not limitation, said other operations include forming a third active layer which is stacked with the first active layer and the second active layer, and which comprises third MOSFETs which each correspond to a third dopant type. In one such embodiment, each transistor of a third memory cell of a third memory array is one of the third MOSFETs—e.g., wherein the second active layer is between the first active layer and the third active layer. In various embodiments, a cell responsiveness of the first memory array is substantially greater than that of the second memory array, as well as that of the third memory array. Alternatively or in addition, a cell density of the first memory array is substantially less than that of the second memory array, as well as that of the third memory array.

In some embodiments, method 200 further comprises other operations (not shown) by which the IC die is to additionally or alternatively include peripheral circuit logic which facilitates access to the first SRAM array and/or the second memory array. For example, such peripheral circuit logic instead comprise the third MOSFETs described above.

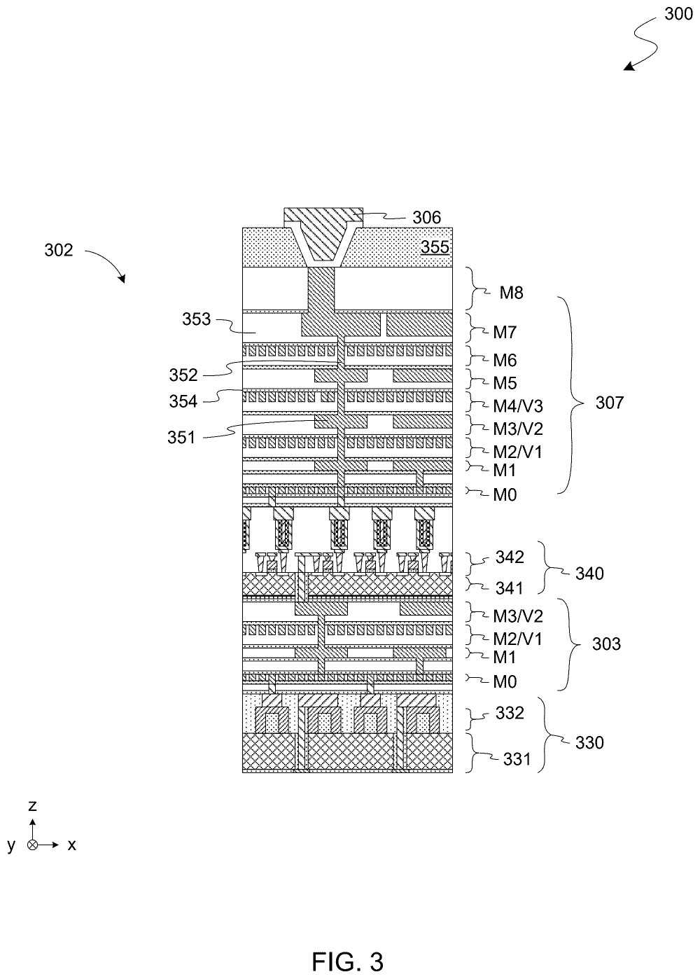

FIG. 3 shows features of an IC system 300 comprising a vertically stacked arrangement of heterogeneous single MOS memory arrays according to an embodiment. In various embodiments, IC system 300 provides functionality such as that of device 100—e.g., wherein structures of IC system 300 are provided by one or more operations of method 200.

As shown in FIG. 3, IC system 300 comprises lateral surfaces each along a respective x-y plane that may be defined or taken at any vertical position of IC system 300. The lateral surface of the x-y plane is orthogonal to a vertical or build-up dimension as defined by the z-axis. In FIG. 3, IC system 300 includes an IC die 302 which, for example, comprises a monolithic (or alternatively, a composite) IC structure including multiple heterogeneous active layers which are stacked with each other. In an embodiment, the IC structure of IC die 302 further comprises metallization layers which are variously disposed each between a respective two of the active layers, or (for example) on a topmost one of the active layers.

In some embodiments, the IC structure includes, or is formed on, any of various substrate materials (e.g., comprising the illustrative semiconductor layer 331 shown) which are suitable for the fabrication of transistor circuitry. The semiconductor layer 331 may include that of a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In the example embodiment shown, an active layer 330 of IC die 302 comprises semiconductor layer 331 and transistors 332 (more particularly, MOSFETs 332) which are variously formed in or on semiconductor layer 331. Transistors 332—e.g., some or all transistors of active layer 330—are single MOS transistors which each correspond to some first dopant type. In some embodiments, MOSFETs 332 are each of a same transistor topology type which (for example) includes any of one or more planar transistor topology types and/or one or more non-planar transistor topology types. In the example embodiment shown, MOSFETs 332 are each of a finFET (e.g., a tri-gate transistor) topology type. However, MOSFETs 332 instead are each of a gate-all-around transistor topology type (such as a nanowire type, or a nanoribbon type), in other embodiments.

In an embodiment, IC die 302 further comprises metallization layers 303 which are disposed on a back side of active layer 330. As used herein, the term “metallization layer” describes layers with interconnections or wires that provide electrical routing, generally formed of metal or other electrically and thermally conductive material. In IC die 302, adjacent metallization layers may be formed of different materials and by different methods. Adjacent metallization layers, such as metallization interconnects 351, are interconnected by vias, such as vias 352, that may be characterized as part of the metallization layers or between the metallization layers. As shown, in some embodiments, metallization layers 303 are formed over and immediately adjacent transistors 332. In the illustrated example, metallization layers 303 include M0, V0, M1, M2/V1, and M3/V2.

However, metallization layers 303 may include any number of metallization layers such as four or more metallization layers.

In some embodiments, the IC structure of IC die 302 includes another material layer (not shown) on which semiconductor layer 331 is formed—e.g., wherein the other material layer is a semiconductor substrate on which additional transistors and/or other circuit components are formed. For example, such additional transistors are those of peripheral circuit logic (e.g., comprising sense amplifiers, driver circuits, or the like) which facilitate access to various memory arrays of IC die 302. In one such embodiment, one or more metallization layers (not shown) are between said other material layer and semiconductor layer 331—e.g., wherein the other material layer comprises transistors of row decoder circuitry 120, column circuitry 122, row decoder circuitry 140, control circuitry 150, column circuitry 160, and/or host logic circuitry 170.

In an embodiment, another active layer 340 of IC die 302 comprises a semiconductor layer 341 and transistors 342 (i.e., MOSFETs 342) which are variously formed in or on semiconductor layer 341. MOSFETs 342—e.g., some or all transistors of active layer 340—are single MOS transistors which each correspond to some second dopant type which, for example, is the same as (or alternatively, is different than) the first dopant type. By way of illustration and not limitation, MOSFETs 332 and MOSFETs 342 are each a respective type of NMOS transistor (or, for example, are each a respective type of PMOS transistor). In an alternate embodiment, MOSFETs 332 are each a respective type of NMOS transistor and MOSFETs 342 are each a respective type of PMOS transistor, or vice versa. In some embodiments, MOSFETs 342 are each of a same transistor topology type (such as the illustrative planar transistor type shown) which, for example, is different than a transistor topology type of MOSFETs 332.

In the example embodiment shown, active layers 330, 340 are vertically stacked in a back-to-face arrangement relative to each other—e.g., wherein metallization layers 303 and a portion of semiconductor layer 341 are disposed between transistors 342 and active layer 330. In some embodiments, IC die 302 further comprises further comprises metallization layers 307 which are disposed on a back side of active layer 340. In the illustrated example, metallization layers 307 include M0, M1, M2/V1, M3/V2, M4/V3, and M5-M8. However, metallization layers 307 may include any number of metallization layers such as eight or more metallization layers.

Metallization layers 303, 307 are embedded within dielectric materials 353, 354. In the example of FIG. 3, package-level interconnects 306 are provided on or over a back of IC die 302—e.g., as bumps over a passivation layer 355. In some embodiments, IC system 300 is attached to a circuit board, a substrate, or any of various other suitable devices (not shown) by package-level interconnects 306. However, package-level interconnects 306 may be provided using any suitable interconnect structures such as bond pads, solder bumps, etc. Interconnectivity of some or all of transistors 332, 342 (and other transistors, etc.), signal routing in a separation layer between channel stack structures, and routing to an outside device (not shown), is variously provided with some or all of metallization layers 303, metallization layers 307, and package-level interconnects 306.

In various embodiments, a first memory array of IC die 302 comprises first memory cells (SRAM cells, for example) which variously comprise respective ones of transistors 332. For example, the first memory array corresponds functionally to memory array 110—e.g., wherein memory cells 112 each comprise a different respective one or more of MOSFETs 332. In one such embodiment, a SRAM array comprises MOSFETs 332, wherein a first memory cell of the SRAM array is of a four transistor (4T) memory cell type, and comprises four of the MOSFETs 332.

In one such embodiment, a second memory array of IC die 302 comprises second memory cells (DRAM cells, for example) which variously comprise respective ones of transistors 342. For example, the second memory array corresponds functionally to memory array 130—e.g., wherein MOSFETs 342 are each a respective one of select transistors 132. In some embodiments, the second memory array comprises any of various suitable dynamic random access memory (DRAM) arrays. By way of illustration and not limitation, a given one of the second memory cells is of a one transistor, n capacitor (1T-nC) DRAM cell type, where n is a positive integer. In another embodiment, one of the second memory cells is of a single transistor cell type—e.g., wherein a gate of said memory cell comprises a ferroelectric material, a charge trapping material, or the like. In some embodiments, the second memory array comprises a three-dimensional (3D) cross-point memory array.

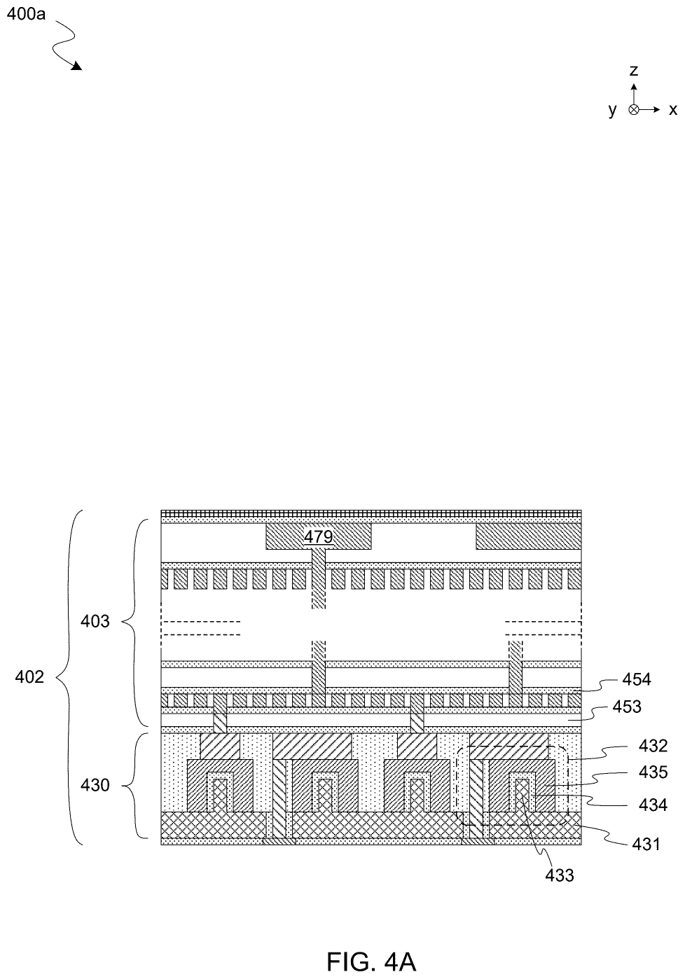

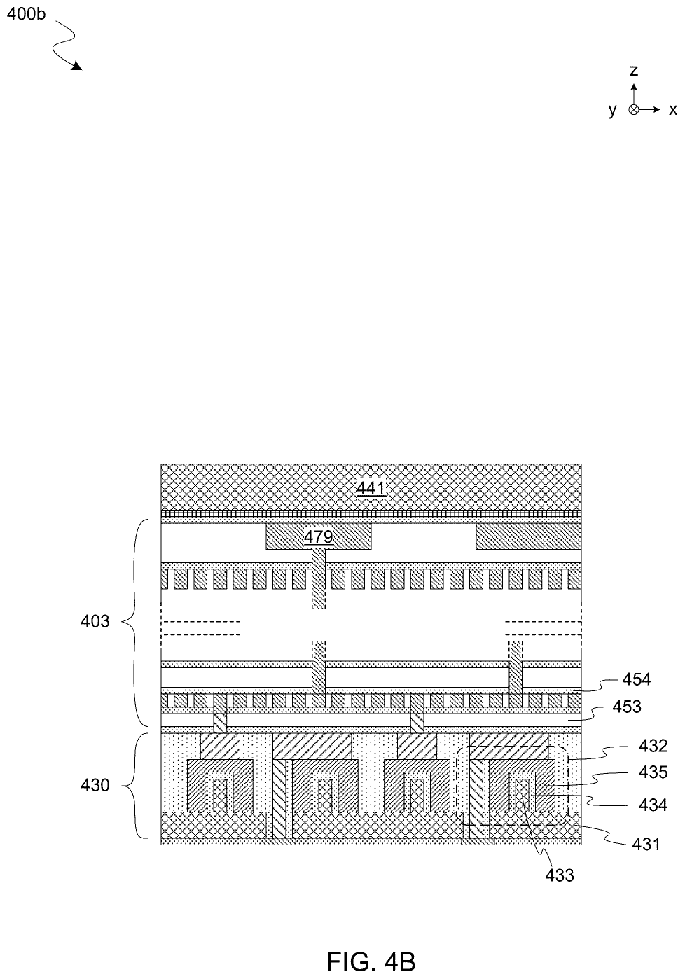

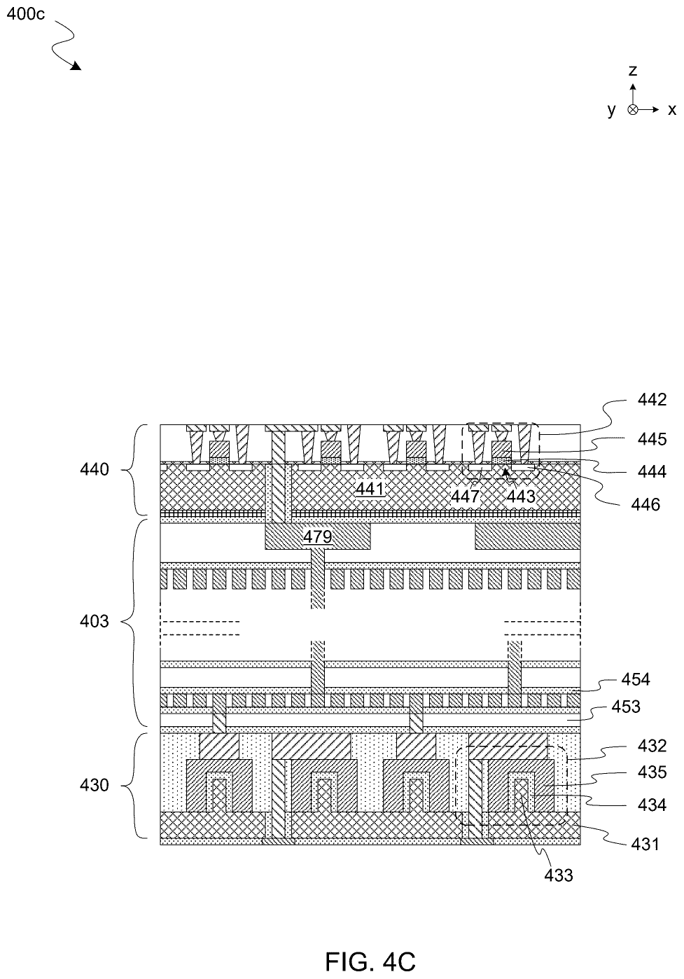

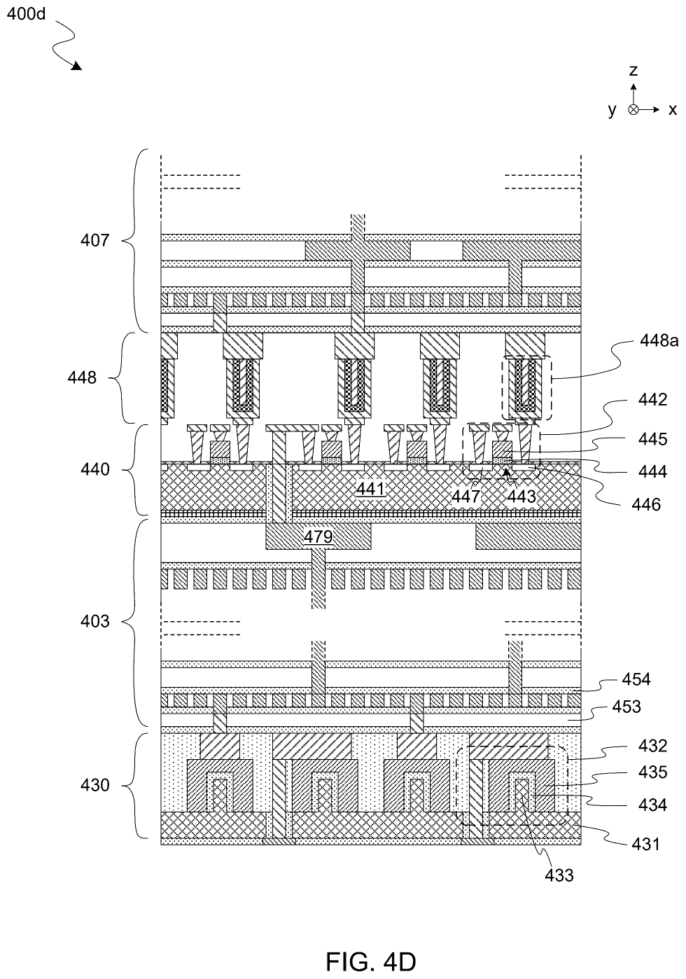

FIGS. 4A through 4D show respective stages 400a-400d of processing to manufacture an IC device comprising heterogeneous stacked memory arrays according to an embodiment. Processing such as that illustrated by stages 400a-400d provides structures such as some or all of those of device 100 or IC system 300—e.g., wherein said processing includes one or more operations of method 200.

Referring now to FIG. 4A, at stage 400a, circuit structures 402 are fabricated or otherwise provided for inclusion in an IC die structure according to an embodiment. Circuit structures 402 comprises and active layer 430 and metallization layers 403 thereon. For example, active layer 430 and metallization layers 403 correspond functionally to active layer 330 and metallization layers 303 (respectively), in some embodiments. In various embodiments, circuit structures 402 further comprise one or more other active layers and metallization layers (not shown). In one such embodiment, circuit structures 402 further comprise another active layer and other metallization layers, wherein a front side of active layer 430 is hybrid bonded to or otherwise coupled with said other metallization layers.

In the example embodiment shown, active layer 430 comprises a semiconductor layer 431 and first (single MOS) MOSFETs which are variously formed therein or thereon. By way of illustration and not limitation, one such MOSFET of active layer 430—transistor 432—comprises a fin structure 433, a gate insulator 434, and a gate electrode 435. Semiconductor layer 431 has formed therein or thereon source or drain structures (not shown) of transistor 432, wherein said source or drain structures are on opposite respective ends of fin structure 433. In an embodiment, a conduction of current in fin structure 433 is controlled by a voltage at gate electrode 435, wherein gate insulator 434 is disposed around fin structure 433 to facilitate insulation from gate electrode 435.

Metallization layers 403 comprise patterned interconnect structures 479 which are variously surrounded by or otherwise at least partially insulated with dielectric material 453, dielectric material 454. In an embodiment, a first memory array comprises the first MOSFETs of active layer 430, wherein metallization layers 403 facilitate coupling within the first memory array and/or coupling of the first memory array to other circuitry. For example, interconnect structures 479 provide bit lines, word lines, and/or other interconnect structures to variously provide coupling within a cell of the first memory array, coupling between cells of the first memory array, coupling between the first memory array and peripheral circuit logic, and/or coupling between the first memory array and another memory array. In one example embodiment, the first memory array is a SRAM memory array.

At stage 400b, a semiconductor layer 441 is formed on a top surface of metallization layers 403. Semiconductor layer 441 comprises any of various suitable semiconductor materials, such as that of semiconductor layer 431, or that of another active layer (if any) of circuit structures 402. In an embodiment, formation of semiconductor layer 441 on circuit structures 402 comprises operations which, for example, are adapted from any of various conventional semiconductor layer transfer techniques. Some embodiments are not limited with respect to such techniques, which are not detailed herein to avoid obscuring features of said embodiments.

At stage 400c, additional semiconductor fabrication processes have been performed to provide an active layer 440 which includes single MOS transistor structures variously formed in or on semiconductor layer 441. In some embodiments, second MOSFETs of active layer 440 are of a different transistor topology type than that of transistor 432 (and/or of one or more other transistors of active layer 430). In the example embodiment shown, transistor 432 is of a non-planer transistor type (more particularly, a tri-gate transistor type), whereas a transistor 442 of active layer 440 is of a planar transistor type.

For example, transistor 442 comprises a channel region 443 a gate insulator 444, a gate electrode 445 which, for example, correspond functionally to fin structure 433, gate insulator 434, and gate electrode 435 (respectively). Channel region 443 is operable to selectively conduct current between source or drain regions 446, 447 of transistor 442 based on a voltage at gate electrode 445. In an embodiment, active layer 430 is vertically stacked with active layer 440 at stage 400c—e.g., wherein metallization layers 403 and a portion of semiconductor layer 441 are between active layer 430 and the second MOSFETs of active layer 440.

At stage 400d, other fabrication processes have been performed to provide additional integrated circuit structures on active layer 440. For example, such additional integrated circuit structures comprise storage capacitors 448 of a memory array which also includes some or all of the MOSFETs of active layer 440. Furthermore, the additional processing forms metallization layers 407 on the storage capacitors 448. In the example embodiment shown, a memory cell of the memory array comprises transistor 432 and a storage capacitor 448a—e.g., wherein the memory cell is adapted from any of various existing DRAM cell designs.

In an embodiment, metallization layers 407 provide bit lines, word lines, and/or other interconnect structures to variously provide coupling within a cell of the memory array, coupling between cells of the memory array, coupling between the memory array and peripheral circuit logic, and/or coupling between the memory array and another memory array. In various alternative embodiments, some or all of active layer 440, storage capacitors 448, and metallization layers 407 are instead coupled to circuit structures 402 via a hybrid bonding process—e.g., wherein active layer 440 is fabricated separately from circuit structures 402 prior to said process.

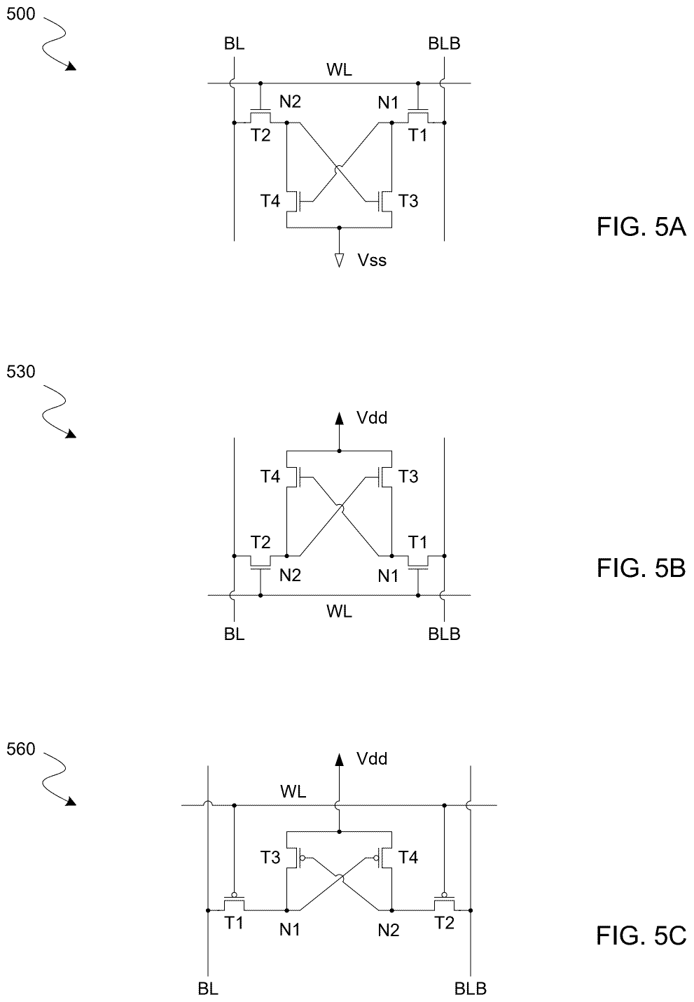

FIGS. 5A-5C illustrate circuit diagrams of 4T SRAM bit-cells, any one of which may be implemented in memory array 110 or IC die 302, for example. In various embodiments, memory cells such as those shown in one of FIGS. 5A-5C, are provided with operations of method 200.

In FIG. 5A, a 4T SRAM bit-cell 500 comprises two NMOS access transistors T1, T2 and two NMOS pull-down transistors T3, T4. The access transistor T1 of bit-cell 500 is coupled across a wordline WL and a bitline BLB, wherein the access transistor T2 of bit-cell 500 is coupled across the wordline WL and another bitline BL (which is to provide an output signal which is complementary to that from bitline BLB). A cross-coupled configuration of the pull-down transistors T3, T4 enables either of two nodes N1, N2 of bit-cell 500 to be selectively brought toward a supply voltage Vss. During operation of bit-cell 500, bitlines BL and BLB may be pre-charged to a higher supply voltage Vcc.

In FIG. 5B, a 4T SRAM bit-cell 530 comprises two NMOS access transistors T1, T2 and two NMOS pull-up transistors T3, T4. The access transistors T1, T2 of bit-cell 530 have a similar configuration relative to a wordline WL and bitlines BL, BLB, wherein a cross-coupled configuration of the pull-up transistors T3, T4 enables either of two nodes N1, N2 of bit-cell 530 to be selectively brought toward a supply voltage Vdd. During operation of bit-cell 530, bitlines BL and BLB may be pre-charged to Vss.

In FIG. 5C, a 4T SRAM bit-cell 560 comprises two PMOS access transistors T1, T2 and two PMOS pull-up transistors T3, T4. The access transistors T1, T2 of bit-cell 560 have a similar configuration relative to a wordline WL and bitlines BL, BLB, wherein a cross-coupled configuration of the pull-up transistors T3, T4 enables either of two nodes N1, N2 of bit-cell 560 to be selectively brought toward a supply voltage Vdd.

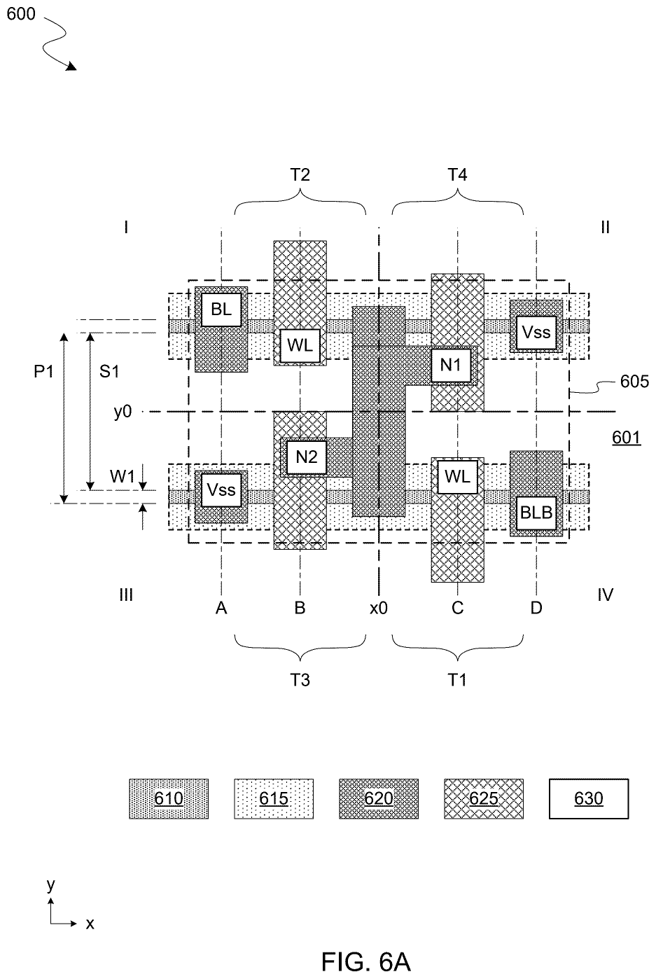

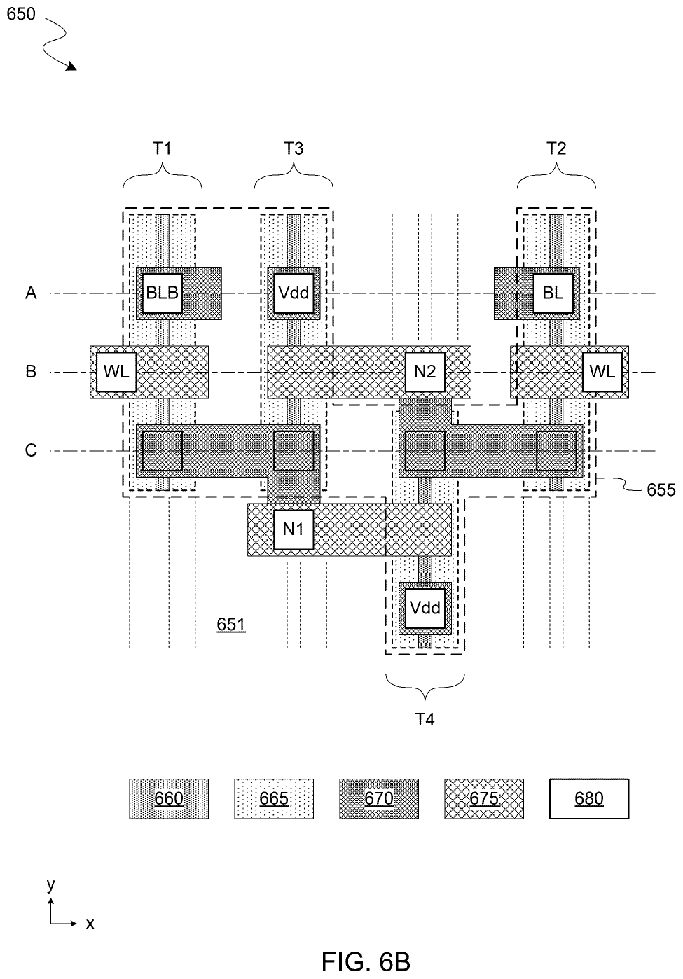

Any of the 4T SRAM bit-cells 500, 530, 560 may benefit from advantageously high transistor drive currents, which may also facilitate their further implementation with fins and nanoribbons of a smaller transverse width (e.g., W1 of FIG. 6A). However, 4T SRAM bit-cells benefit most from the reduction in leakage currents possible with low temperature operation. With this reduction in leakage current, the performance of 4T SRAM bit-cells, such as any of those illustrated in FIG. 5A-5C, is much more comparable to 6T bit-cell circuits. An approximately 2.5× improvement in SRAM density may then be realized through the elimination of two transistors from each bit-cell without suffering a concomitant SRAM performance loss. This improved cell density facilitates the integration of an SRAM array with any of various DRAM (or other) types of memory arrays which have a relatively high cell density. For example, a significant increase in SRAM density is possible for SRAMs integrated into a system capable of maintaining very low temperatures during operation.

The performance benefits of very low temperature operation are more dramatic for electrons than holes as a function of their mobility and/or saturation velocity being more greatly enhanced. Accordingly, 4T SRAM cells comprising only NMOS transistors (e.g., 4T SRAM bit-cells 500 and 530) are particularly advantageous to integrate into circuitry, that is part of a low-temperature platform.

FIG. 6A is a layout of a 4T SRAM bit-cell 600 having some or all of the features of the bit-cell circuit 500 illustrated in FIG. 5A, in accordance with one example embodiment. As shown in FIG. 6A, 4T SRAM bit-cell 600 includes only two fins 610. Fins 610 are substantially parallel, each having a longitudinal length in one (e.g., x) direction over a plane of a substrate 601 that spans the width of cell boarder 605. Because all four transistors are NMOS, there are only two active regions 615, each surrounding one of fins 610.

As further illustrated in FIG. 6A, each of the pair of pull-down transistors T3, T4 and pair of access transistors T1, T2 have a gate electrode with a longitudinal length extending in one direction orthogonal to that of fins 610 (e.g., y-direction). A gate electrode 625 of a first pull-down transistor T3 has a centerline B through a thickness of gate electrode 625 substantially orthogonal to the x-y plane of substrate material 601. Centerline B passes through another gate electrode 625 of one access transistor T2, which is colinear with a first pull-down transistor T3. Bit-cell boarder 605 is bifurcated in the x-dimension by a straight line y0, which passes through a space between these two colinear gate electrodes 625. A gate electrode 625 of the second pull-down transistor T4 has another centerline C through the thickness of gate electrode 625 orthogonal to the x-y plane of substrate material 601. Centerline C passes through a gate electrode 625 of the second access transistor T1, which is colinear with the second pull-down transistor T4. Bit-cell bifurcation line y0 also passes through a space between these two colinear gate electrodes 625.

Individual ones of the pair of pull-down transistors T3, T4 and pair of access transistors T1, T2 have source/drain contact metallization that also has a longitudinal length extending in one direction orthogonal to that of fins 610 and parallel to gate electrodes 625 (e.g., y-direction). Bit-cell boarder 605 may be bifurcated in the y-dimension by a straight line x0, which passes through a centerline of a portion of source/drain contact metallization 620 that intersects both fins 610 and spans the space between fins 610. Center portions of source/drain contact metallization 620 are electrically coupled each to a gate electrode 625 of a respective one of the pull-down transistors T3, T4 through interconnect metallization 630, defining storage nodes N1, N2. Cell bifurcation line x0 passes through a space between these two features of storage node interconnect metallization 630. Cell bifurcation line y0 also passes through a space between these two features of storage node interconnect metallization 630.

As further illustrated in FIG. 5A, each of the pair of pull-down transistors T3, T4 and access transistors T1, T2 have a second source/drain that is in contact with one feature of source/drain contact metallization 620. A first pair of these features of source/drain contact metallization 620 are colinear, sharing a centerline A that extends through a thickness of the source/drain contact metallization 620. A second pair of these features of source/drain contact metallization 620 are colinear and share centerline D. Cell bifurcation line y0 passes through a space between each pair of colinear features of source/drain contact metallization 620. Bitline BL is coupled into one access transistor T2 through one feature of source/drain contact metallization 620 on centerline A. Bitline bar BLB is coupled into another access transistor T1 through one feature of source/drain contact metallization 620 on centerline D. Vss is coupled into one pull-down transistor T3 through one feature of source/drain contact metallization 620 on centerline A and into another access transistor T4 through one feature of source/drain contact metallization 620 on centerline D. Centerlines A, B, C and D are all substantially parallel and advantageously at an equal pitch.

Accordingly, the bit-cell bifurcation lines x0 and y0 define four quadrants I, II, III and IV of bit-cell 600. Quadrants I and IV are mirror images of each other along a first plane of symmetry orthogonal to a plane of substrate 601 that passes through the intersection of the bit-cell bifurcation lines x0 and y0. Quadrants II and III are similarly mirror images of each other along a second plane of symmetry also passing through the intersection of the bit-cell bifurcation lines x0 and y0 and orthogonal to the first plane of symmetry. In other words, the four quadrants I-IV of bit-cell 600 have 180° rotational symmetry.

Notably, the area within bit-cell boarder 605 is approximately 2.5× smaller than the area of some typical 6T SRAM memory cell designs, which translates into an approximate 2.5× improvement in SRAM cell density for given minimum feature size and space design rule. For further embodiments where SRAM bit-cell 600 is implemented into a system with sufficient active cooling to maintain at least SRAM bit-cell 600 at a very low temperature (e.g., <<0° C.), leakage losses of SRAM bit-cell 600 are no worse than those of some 6T SRAM cells, so that the density improvement between a 6T bit-cell and a 4T bit-cell is not at the expense of SRAM leakage performance.

In some further embodiments, a transverse width of fins 610 facilitates relatively high transistor drive currents at very low temperatures, which in turn enable relatively low bit-cell capacitance for a given bit-cell height. For example, pitch P1 may comprise a larger space S1 as transverse width W1 is reduced. The smaller transverse width W1 may be reduced to be significantly smaller than the transverse width of transistors in logic circuitry blocks outside of an SRAM array. For example, within SRAM bit-cell 600 transverse width W1 may be 1-2 nm while the equivalent width within logic circuitry is 3-4 nm.

FIG. 6B is a layout of another 4T SRAM bit-cell 650 having some or all of the features of bit-cell circuit 530, in accordance with a different embodiment. As shown in FIG. 6B, 4T SRAM bit-cell 650 spans four fins 660 which are substantially parallel, each having a longitudinal length in one (e.g., y) direction over a plane of a substrate 651. The fins 660 are variously surrounded each by a respective active region 665.

As further illustrated in FIG. 6B, each of the pair of pull-up transistors T3, T4 and pair of access transistors T1, T2 have a gate electrode with a longitudinal length extending in one direction orthogonal to that of fins 660 (e.g., x-direction).

In the example embodiment shown, transistors T1, T2, T3 are substantially aligned with each other along the y-axis shown. For example, respective portions of source/drain contact metallization 670 for transistors T1, T2, T3 share a centerline A, wherein respective gate electrodes 675 share a centerline B, and wherein respective other portions of source/drain contact metallization 670 each extend along a line C.

By contrast, pull-up transistor T4, which is located along the x-axis between transistors T2, T3, is partially offset along the y-axis from the aligned transistors T1, T2, T3. For example, one of the portions of source/drain contact metallization 670 extends along the line C to couple to a source/drain terminal of transistor T4. As a result, a bit-cell boarder 655 of bit-cell 650 is of a non-rectilinear shape that, for example, accommodates tessellation of bit-cell 650 with other bit-cells of the same memory array.

With various portions of an interconnect metallization 680, access transistor T1 of bit-cell 650 is coupled across a wordline WL and a bitline BLB, wherein the access transistor T2 of bit-cell 650 is coupled across the wordline WL and another bitline BL. Other portions of interconnect metallization 680 variously facilitate a cross-coupled configuration of the pull-down transistors T3, T4, which enables either of two nodes N1, N2 of bit-cell 650 to be selectively brought toward a supply voltage Vdd.

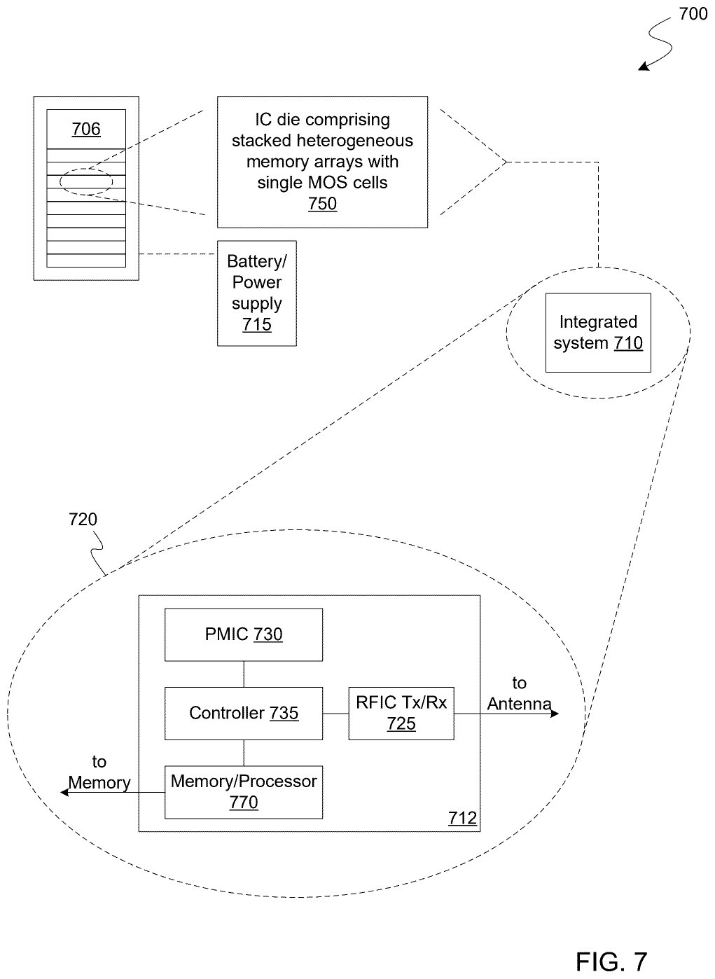

FIG. 7 illustrates a schematic of a data server machine including an IC device 700 which comprises a vertically stacked arrangement of heterogeneous memory arrays comprising respective single MOS memory cells, in accordance with one or more embodiments described elsewhere herein. Server machine 706 may be any commercial server, for example, including any number of high-performance computing platforms disposed within a rack and networked together for electronic data processing, which in the exemplary embodiment includes one or more devices 750, an IC die of which comprises a stacked arrangement of heterogeneous memory arrays comprising a 4T SRAM array and a relatively more dense (e.g., DRAM) array.

Also as shown, server machine 706 includes a battery and/or power supply 715 to provide power to devices 750, and to provide, in some embodiments power delivery functions such as power regulation. Devices 750 may be deployed as part of a package-level integrated system 710. Integrated system 710 is further illustrated in the expanded view 720. In the exemplary embodiment, integrated system 710 includes an integrated circuitry 770 (labeled “Memory/Processor”) includes at least one memory array (e.g., RAM), and/or at least one processor core (e.g., a microprocessor, a multi-core microprocessor, or graphics processor, or the like) having the characteristics discussed herein. In an embodiment, integrated circuitry 770 is a microprocessor a vertically stacked arrangement of multiple memory arrays which, for example, comprise a 4T SRAM array and a relatively small pitch DRAM array. Integrated circuitry 770 may be further coupled to (e.g., communicatively coupled to) a board, a substrate, or an interposer along with, one or more of a power management integrated circuit (PMIC) 730, RF (wireless) integrated circuitry (RFIC) 725 including a wideband RF (wireless) transmitter and/or receiver (TX/RX) (e.g., including a digital baseband and an analog front end module further comprises a power amplifier on a transmit path and a low noise amplifier on a receive path), and a controller 735.

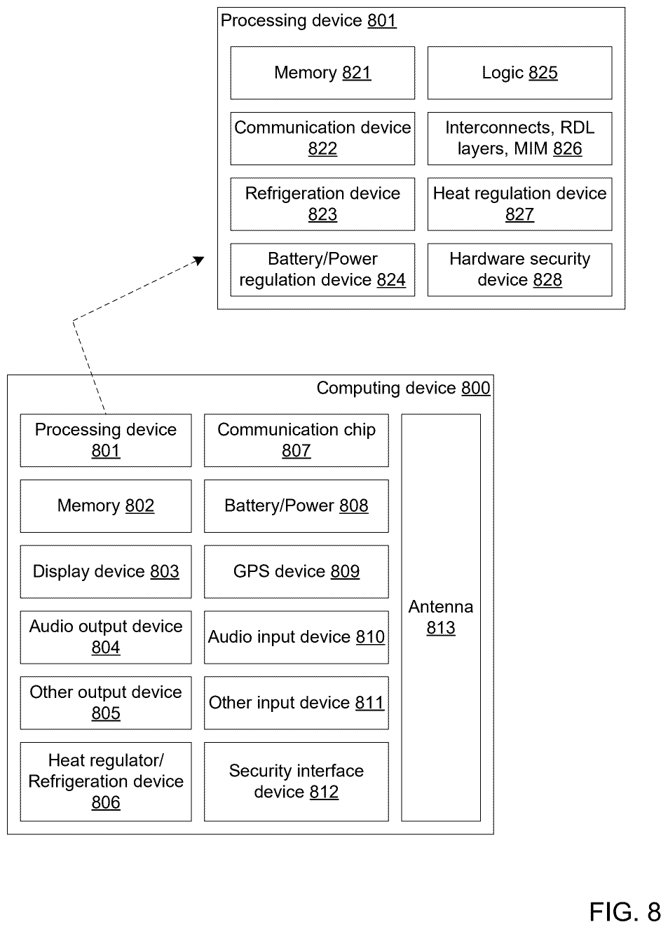

FIG. 8 is a block diagram of a computing device 800 in accordance with some embodiments. For example, one or more components of computing device 800 may include any of the devices or structures discussed elsewhere herein. Exemplary components are illustrated in FIG. 8 as included in computing device 800, but any one or more of these components may be omitted or duplicated, as suitable for the application. In some embodiments, some of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled.

Computing device 800 may include a processing device 801 (e.g., one or more processing devices). As used herein, the term processing device or processor indicates a device that processes electronic data from registers and/or memory to transform that electronic data into other electronic data that may be stored in registers and/or memory. Processing device 801 may include a memory 821, a communication device 822, a refrigeration/active cooling device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 801 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 821 includes memory that shares a die with processing device 801. This memory may be used as cache memory and may include embedded dynamic random-access memory (eDRAM) or spin transfer torque magnetic random-access memory (STT-M RAM).

Computing device 800 may include a heat regulation/refrigeration device 806. Heat regulation/refrigeration device 806 may maintain processing device 801 (and/or other components of computing device 800) at a predetermined low temperature during operation. This predetermined low temperature may be of various suitable temperatures adapted from conventional circuit cooling techniques.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium.

Communication chip 807 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project, etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a global positioning system (GPS) device 809 (or corresponding interface circuitry, as discussed above). GPS device 809 may be in communication with a satellite-based system and may receive a location of computing device 800, as known in the art.

Computing device 800 may include another output device 805 (or corresponding interface circuitry, as discussed above). Examples include an audio codec, a video codec, a printer, a wired or wireless transmitter for providing information to other devices, or an additional storage device.

Computing device 800 may include another input device 811 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, managing access lists, malware detection, or spyware detection,

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

In one or more first embodiments, an integrated circuit (IC) die structure comprises a first active layer comprising first metal oxide semiconductor field effect transistors (MOSFETs) which each correspond to a first dopant type, wherein a first static random access memory (SRAM) array comprises the first MOSFETs, wherein a first memory cell of the first SRAM array is of a four transistor (4T) memory cell type, and comprises four of the first MOSFETs, and a second active layer which is stacked with the first active layer, the second active layer comprising second MOSFETs which each correspond to a second dopant type, wherein each transistor of a second memory cell of a second memory array is one of the second MOSFETs, wherein a first cell density of the first SRAM array is less than a second cell density of the second memory array.

In one or more second embodiments, further to the first embodiment, a first responsiveness of the first MOSFETs is greater than a second responsiveness of the second MOSFETs by at least 5% of the first responsiveness.

In one or more third embodiments, further to the first embodiment or the second embodiment, the first dopant type is the same as the second dopant type.

In one or more fourth embodiments, further to any of the first through third embodiments, each transistor of the first SRAM array is a respective n-type transistor.

In one or more fifth embodiments, further to any of the first through fourth embodiments, the second memory array comprises a dynamic random access memory (DRAM) array.

In one or more sixth embodiments, further to any of the first through fifth embodiments, each transistor of the first SRAM array corresponds to the first dopant type.

In one or more seventh embodiments, further to the sixth embodiment, each transistor of the first active layer corresponds to the first dopant type.

In one or more eighth embodiments, further to the sixth embodiment, each transistor of the second memory array corresponds to the second dopant type.

In one or more ninth embodiments, further to any of the first through fifth embodiments, the IC die structure further comprises a third active layer which is stacked with the first active layer and the second active layer, the third active layer comprising third MOSFETs which each correspond to a third dopant type, wherein each transistor of a third memory cell of a third memory array is one of the third MOSFETs, wherein the second active layer is between the first active layer and the third active layer, a responsiveness of the second memory cell is greater than another responsiveness of the third memory cell, and the second cell density of the second memory array is less than a third cell density of the third memory array.

In one or more tenth embodiments, further to any of the first through fifth embodiments, the IC die structure further comprises a third active layer which is stacked with the first active layer and the second active layer, wherein peripheral circuit logic to access the first SRAM array and the second memory array comprises third MOSFETs of the third active layer.

In one or more eleventh embodiments, a method comprises forming a first active layer of an integrated circuit (IC) die, wherein the first active layer comprises first metal oxide semiconductor field effect transistors (MOSFETs) which each correspond to a first dopant type, forming first metallization layers on the first active layer, forming a second active layer of the IC die, wherein the second active layer is stacked with the first active layer, the second active layer comprising second MOSFETs which each correspond to a second dopant type, and forming second metallization layers on the second active layer, wherein a first static random access memory (SRAM) array comprises the first MOSFETs, wherein a first memory cell of the first SRAM array is of a four transistor (4T) memory cell type, and comprises four of the first MOSFETs, wherein each transistor of a second memory cell of a second memory array is one of the second MOSFETs, and wherein a first cell density of the first SRAM array is less than a second cell density of the second memory array.

In one or more twelfth embodiments, further to the eleventh embodiment, a first responsiveness of the first MOSFETs is greater than a second responsiveness of the second MOSFETs by at least 5% of the first responsiveness.

In one or more thirteenth embodiments, further to the eleventh embodiment or the twelfth embodiment, the first dopant type is the same as the second dopant type.

In one or more fourteenth embodiments, further to any of the eleventh through thirteenth embodiments, each transistor of the first SRAM array is a respective n-type transistor.

In one or more fifteenth embodiments, further to any of the eleventh through fourteenth embodiments, the second memory array comprises a dynamic random access memory (DRAM) array.

In one or more sixteenth embodiments, further to any of the eleventh through fifteenth embodiments, each transistor of the first SRAM array corresponds to the first dopant type.

In one or more seventeenth embodiments, further to the sixteenth embodiment, each transistor of the first active layer corresponds to the first dopant type.

In one or more eighteenth embodiments, further to the sixteenth embodiment, each transistor of the second memory array corresponds to the second dopant type.

In one or more nineteenth embodiments, further to any of the eleventh through fifteenth embodiments, the method further comprises forming a third active layer which is stacked with the first active layer and the second active layer, the third active layer comprising third MOSFETs which each correspond to a third dopant type, wherein each transistor of a third memory cell of a third memory array is one of the third MOSFETs, wherein the second active layer is between the first active layer and the third active layer, a responsiveness of the second memory cell is greater than another responsiveness of the third memory cell, and the second cell density of the second memory array is less than a third cell density of the third memory array.

In one or more twentieth embodiments, further to any of the eleventh through fifteenth embodiments, the method further comprises forming a third active layer which is stacked with the first active layer and the second active layer, wherein peripheral circuit logic to access the first SRAM array and the second memory array comprises third MOSFETs of the third active layer.

In one or more twenty-first embodiments, a system comprises a substrate, and a component coupled to the substrate, the component comprising an integrated circuit (IC) die, wherein the IC die comprises a first active layer comprising first metal oxide semiconductor field effect transistors (MOSFETs) which each correspond to a first dopant type, wherein a first static random access memory (SRAM) array comprises the first MOSFETs, wherein a first memory cell of the first SRAM array is of a four transistor (4T) memory cell type, and comprises four of the first MOSFETs, and a second active layer which is stacked with the first active layer, the second active layer comprising second MOSFETs which each correspond to a second dopant type, wherein each transistor of a second memory cell of a second memory array is one of the second MOSFETs, wherein a first cell density of the first SRAM array is less than a second cell density of the second memory array.

In one or more twenty-second embodiments, further to the twenty-first embodiment, a first responsiveness of the first MOSFETs is greater than a second responsiveness of the second MOSFETs by at least 5% of the first responsiveness.

In one or more twenty-third embodiments, further to the twenty-first embodiment or the twenty-second embodiment, the first dopant type is the same as the second dopant type.

In one or more twenty-fourth embodiments, further to any of the twenty-first through twenty-third embodiments, each transistor of the first SRAM array is a respective n-type transistor.

In one or more twenty-fifth embodiments, further to any of the twenty-first through twenty-fourth embodiments, the second memory array comprises a dynamic random access memory (DRAM) array.

In one or more twenty-sixth embodiments, further to any of the twenty-first through twenty-fifth embodiments, each transistor of the first SRAM array corresponds to the first dopant type.

In one or more twenty-seventh embodiments, further to the twenty-sixth embodiment, each transistor of the first active layer corresponds to the first dopant type.

In one or more twenty-eighth embodiments, further to the twenty-sixth embodiment, each transistor of the second memory array corresponds to the second dopant type.

In one or more twenty-ninth embodiments, further to any of the twenty-first through twenty-fifth embodiments, the IC die further comprises a third active layer which is stacked with the first active layer and the second active layer, the third active layer comprising third MOSFETs which each correspond to a third dopant type, wherein each transistor of a third memory cell of a third memory array is one of the third MOSFETs, wherein the second active layer is between the first active layer and the third active layer, a responsiveness of the second memory cell is greater than another responsiveness of the third memory cell, and the second cell density of the second memory array is less than a third cell density of the third memory array.

In one or more thirtieth embodiments, further to any of the twenty-first through twenty-fifth embodiments, the IC die further comprises a third active layer which is stacked with the first active layer and the second active layer, wherein peripheral circuit logic to access the first SRAM array and the second memory array comprises third MOSFETs of the third active layer.

Techniques and architectures for providing integrated circuit structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) die structure comprising:
a first active layer comprising first metal oxide semiconductor field effect transistors (MOSFETs) which each correspond to a first dopant type, wherein a first static random access memory (SRAM) array comprises the first MOSFETs, wherein a first memory cell of the first SRAM array is of a four transistor (4T) memory cell type, and comprises four of the first MOSFETs; and
a second active layer which is stacked with the first active layer, the second active layer comprising second MOSFETs which each correspond to a second dopant type, wherein each transistor of a second memory cell of a second memory array is one of the second MOSFETs;
wherein a first cell density of the first SRAM array is less than a second cell density of the second memory array.

2. The IC die structure of claim 1, wherein a first responsiveness of the first MOSFETs is greater than a second responsiveness of the second MOSFETs by at least 5% of the first responsiveness.

3. The IC die structure of claim 1, wherein the first dopant type is the same as the second dopant type.

4. The IC die structure of claim 1, wherein each transistor of the first SRAM array is a respective n-type transistor.

5. The IC die structure of claim 1, wherein the second memory array comprises a dynamic random access memory (DRAM) array.

6. The IC die structure of claim 1, wherein each transistor of the first SRAM array corresponds to the first dopant type.

7. The IC die structure of claim 6, wherein each transistor of the first active layer corresponds to the first dopant type.

8. The IC die structure of claim 6, wherein each transistor of the second memory array corresponds to the second dopant type.

9. The IC die structure of claim 1, further comprising:
a third active layer which is stacked with the first active layer and the second active layer, the third active layer comprising third MOSFETs which each correspond to a third dopant type, wherein each transistor of a third memory cell of a third memory array is one of the third MOSFETs;
wherein:
the second active layer is between the first active layer and the third active layer;
a responsiveness of the second memory cell is greater than another responsiveness of the third memory cell; and
the second cell density of the second memory array is less than a third cell density of the third memory array.

10. The IC die structure of claim 1, further comprising a third active layer which is stacked with the first active layer and the second active layer, wherein peripheral circuit logic to access the first SRAM array and the second memory array comprises third MOSFETs of the third active layer.

11. A method comprising:
forming a first active layer of an integrated circuit (IC) die, wherein the first active layer comprises first metal oxide semiconductor field effect transistors (MOSFETs) which each correspond to a first dopant type;
forming first metallization layers on the first active layer;
forming a second active layer of the IC die, wherein the second active layer is stacked with the first active layer, the second active layer comprising second MOSFETs which each correspond to a second dopant type; and
forming second metallization layers on the second active layer, wherein a first static random access memory (SRAM) array comprises the first MOSFETs, wherein a first memory cell of the first SRAM array is of a four transistor (4T) memory cell type, and comprises four of the first MOSFETs, wherein each transistor of a second memory cell of a second memory array is one of the second MOSFETs, and wherein a first cell density of the first SRAM array is less than a second cell density of the second memory array.

12. The method of claim 11, wherein a first responsiveness of the first MOSFETs is greater than a second responsiveness of the second MOSFETs by at least 5% of the first responsiveness.

13. The method of claim 11, wherein each transistor of the first SRAM array is a respective n-type transistor.

14. The method of claim 11, wherein the second memory array comprises a dynamic random access memory (DRAM) array.

15. The method of claim 11, wherein each transistor of the first SRAM array corresponds to the first dopant type.

16. A system comprising:
a substrate; and
a component coupled to the substrate, the component comprising an integrated circuit (IC) die, wherein the IC die comprises:
a first active layer comprising first metal oxide semiconductor field effect transistors (MOSFETs) which each correspond to a first dopant type, wherein a first static random access memory (SRAM) array comprises the first MOSFETs, wherein a first memory cell of the first SRAM array is of a four transistor (4T) memory cell type, and comprises four of the first MOSFETs; and
a second active layer which is stacked with the first active layer, the second active layer comprising second MOSFETs which each correspond to a second dopant type, wherein each transistor of a second memory cell of a second memory array is one of the second MOSFETs;
wherein a first cell density of the first SRAM array is less than a second cell density of the second memory array.

17. The system of claim 16, wherein a first responsiveness of the first MOSFETs is greater than a second responsiveness of the second MOSFETs by at least 5% of the first responsiveness.

18. The system of claim 16, wherein each transistor of the first SRAM array is a respective n-type transistor.

19. The system of claim 16, wherein each transistor of the first SRAM array corresponds to the first dopant type.

20. The system of claim 19, wherein each transistor of the second memory array corresponds to the second dopant type.
